(19) United States
(12) Patent Application Publication
(10) Pub. No.: US 2026/0367529 A1
(43) Pub. Date: Nov. 19, 2026

(54) METHOD AND APPARATUS FOR COMPENSATING OVERLAY ERROR IN LITHOGRAPHY PROCESS AND LITHOGRAPHY MACHINE

(71) Applicant: INSTITUTE OF MICROELECTRONICS, CHINESE ACADEMY OF SCIENCES, Beijing (CN)

(72) Inventors: Dinghai Rui, Beijing (CN); Libin Zhang, Beijing (CN); Yayi Wei, Beijing (CN); Yajuan Su, Beijing (CN)

(21) Appl. No.: 19/371,943

(22) Filed: Oct. 28, 2025

(30) Foreign Application Priority Data
May 19, 2025 (CN) 202510642587.4

(51) Int. Cl. G03F 7/00

(52) U.S. Cl. CPC G03F 7/70633; G03F 7/70558; G03F 7/70783; G03F 7/70875

(57) ABSTRACT

A method and an apparatus for compensating an overlay error in a lithography process and a lithography machine are provided, applicable in the field of semiconductor manufacturing. Overlay error distribution data is obtained. Based on the overlay error distribution data and a cubic polynomial which is pre-established and represents a relationship between an overlay error and a position coordinate, estimated values of coefficients in the cubic polynomial is determined to obtain error compensation parameters. A target compensation solution is determined based on the error compensation parameters and a functional relationship between compensation solutions and the error compensation parameters. The compensation solution includes compensation heat doses and compensation stresses. A compensation heat dose is applied to each heat input region of a mask and a compensation stress is applied to each stress compensation point of the mask, based on the target compensation solution.

### CROSS-REFERENCE TO RELATED APPLICATIONS

The present application claims priority to Chinese Patent Application No. 202510642587.4, titled “METHOD AND APPARATUS FOR COMPENSATING OVERLAY ERROR IN LITHOGRAPHY PROCESS AND LITHOGRAPHY MACHINE,” filed on May 19, 2025 with the China National Intellectual Property Administration, which is incorporated herein by reference in its entirety.

### FIELD

The present disclosure relates to the technical field of semiconductor manufacturing, and in particular to a method and an apparatus for compensating an overlay error in a lithography process and a lithography machine.

### BACKGROUND

With the development of semiconductor technology, the integration level of chips has significantly increased, leading to increasingly stringent requirements for an overlay error in a lithography process.

In semiconductor manufacturing, the overlay error refers to an offset between circuit layers, which is quantitatively described by a coordinate deviation between a lithographic pattern and a reference pattern in an X direction and a Y direction. Conventional projection lithography systems rely on optical lenses for overlay error compensation. However, as technology nodes shrink, the compensation approaches a capability limit and fails to meet current lithography quality requirements.

Consequently, reducing an overlay error in a lithography process becomes an issue to be addressed.

### SUMMARY

To address the above issue, a method and an apparatus for compensating an overlay error in a lithography process and a lithography machine are provided according to the present disclosure, to reduce the overlay error in the lithography process.

The following technical solutions are provided according to embodiments of the present disclosure.

In a first aspect, a method for compensating an overlay error in a lithography process is provided according to an embodiment of the present disclosure. The method includes:
obtaining overlay error distribution data;
determining, based on the overlay error distribution data and a cubic polynomial which is pre-established and represents a relationship between an overlay error and a position coordinate, an estimated value of each of coefficients in the cubic polynomial, to obtain error compensation parameters;
determining a target compensation solution based on the error compensation parameters and a functional relationship between compensation solutions and the error compensation parameters, where each of the compensation solutions includes compensation heat doses corresponding to at least 20 heat input regions and compensation stresses corresponding to multiple stress compensation points; and
applying a compensation heat dose to each heat input region of the at least 20 heat input regions of a mask and applying a compensation stress to each stress compensation point of the multiple stress compensation points of the mask based on the target compensation solution.

In an embodiment, the applying a compensation heat dose to each heat input region of the at least 20 heat input regions of a mask based on the target compensation solution includes:
determining a heating pattern based on the compensation heat dose corresponding to the heat input region in the target compensation solution; and
driving, based on the heating pattern, an optical system to modulate a heating light source, and driving a digital micro-mirror device to reflect heating light from the modulated heating light source onto the mask, to apply the compensation heat dose to the heat input region of the mask.

In an embodiment, after driving, based on the heating pattern, an optical system to modulate a heating light source, and driving a digital micro-mirror device to reflect heating light from the modulated heating light source onto the mask, to apply the compensation heat dose to the heat input region of the mask, the method further includes:
for each heat input region of the at least 20 heat input regions,
   obtaining a current temperature of the heat input region through a temperature sensor; and
   dynamically adjusting, based on the current temperature of the heat input region and a target temperature of the heat input region, a state of each of micro-mirrors in the digital micro-mirror device, to cause the current temperature to approach the target temperature, where the target temperature of the heat input region is a temperature that the heat input region approaches after the compensation heat dose is applied.

In an embodiment, the number of the heat input regions is 143.

In an embodiment, the 143 heat input regions are arranged as an equally spaced matrix including 11 heat input regions in a horizontal direction and 13 heat input regions in a vertical direction.

In an embodiment, each of the heat input regions is a rectangular with a length of 3 mm and a width of 2 mm.

In an embodiment, the determining, based on the overlay error distribution data and a cubic polynomial which is pre-established and represents a relationship between an overlay error and a position coordinate, an estimated value of each of coefficients in the cubic polynomial, to obtain error compensation parameters includes:

determining, based on the overlay error distribution data and the cubic polynomial which is pre-established and represents the relationship between the overlay error and the position coordinate, the estimated value of the coefficient in the cubic polynomial through least squares, to obtain the error compensation parameters.

In a second aspect, an apparatus for compensating an overlay error in a lithography process is provided according to an embodiment of the present disclosure. The apparatus includes: an obtaining module, a parameter determination module, a solution determination module, and a compensation module.

The obtaining module is configured to obtain overlay error distribution data under a current lithographic condition.

The parameter determination module is configured to determine, based on the overlay error distribution data and a cubic polynomial which is pre-established and represents a relationship between an overlay error and a position coordinate, an estimated value of each of coefficients in the cubic polynomial, to obtain error compensation parameters.

The solution determination module is configured to determine a target compensation solution based on the error compensation parameters and a functional relationship between compensation solutions and the error compensation parameters, where each of the compensation solutions includes compensation heat doses corresponding to at least 20 heat input regions and compensation stresses corresponding to multiple stress compensation points.

The compensation module is configured to apply a compensation heat dose to each heat input region of the at least 20 heat input regions of a mask and apply a compensation stress to each stress compensation point of the multiple stress compensation points of the mask based on the target compensation solution.

In a third aspect, a lithography machine is provided according to an embodiment of the present disclosure. The lithography machine includes: a controller, a stress actuator, and a local heating system.

The controller is electrically connected to the stress actuator and the local heating system.

The controller is configured to drive the stress actuator to apply a compensation stress to each stress compensation point of stress compensation points of a mask and drive the local heating system to apply a compensation heat dose to each heat input region of heat input regions of the mask, based on the method for compensating the overlay error in the lithography process according to any of embodiments in the first aspect.

In an embodiment, the local heating system includes a digital micro-mirror device, a heating light source, and an optical system.

The local heating system is configured to modulate, in response to driving by the controller, the heating light source through the optical system to focus heating light from the heating light source onto each of micro-mirrors in the digital micro-mirror device, and reflect the heating light onto the mask through the digital micro-mirror device, to apply the compensation heat dose to the heat input region of the mask.

Beneficial effects provided by the present disclosure compared with conventional technologies are described below.

Therefore, in the embodiments of the present disclosure, the compensation stress and the compensation heat doses corresponding to at least 20 heat input regions that are required to compensate for an overlay error are determined based on overlay error distribution data. Stress compensation and pixel-level heat compensation for the mask are implemented to induce a controlled mask deformation, so as to precisely compensate the overlay error in the lithography. Thereby, the overlay error in the lithography is effectively reduced, lithography precision is enhanced, high-precision pattern transfer for a pattern with a small feature size is implemented, product reliability and yield are improved, and cost of large-scale production is reduced.

Furthermore, the method for compensating the overlay error in the lithography process according to the embodiments of the present disclosure is applicable to various lithography technologies such as extreme ultraviolet lithography (EUVL), deep ultraviolet lithography (DUVL), nanoimprint lithography (NIL), and surface plasmon lithography (SPL), which has strong universality. The method provides a high-precision overlay error compensation solution based on heat compensation and stress compensation for fields like high-precision semiconductor manufacturing and micro/nano-structure processing, meeting diverse process and equipment requirements.

### BRIEF DESCRIPTION OF THE DRAWINGS

For more clearly illustrating the technical solutions in the embodiments of the present disclosure or in the conventional technology, drawings referred to describe the embodiments or the conventional technology will be briefly described hereinafter. Apparently, the drawings in the following description are related to some embodiments of the present disclosure, and for those skilled in the art, other drawings may be obtained based on these drawings without any creative efforts.

FIG. 1 is a flowchart of a method for compensating an overlay error in a lithography process according to an embodiment of the present disclosure;

FIG. 2 is a schematic diagram of an overlay error compensation mechanism according to an embodiment of the present disclosure;

FIG. 3 is a vector diagram illustrating an overlay error distribution according to an embodiment of the present disclosure;

FIG. 4 is a schematic diagram illustrating a heating image of compensation heat doses corresponding to heat input regions according to an embodiment of the present disclosure;

FIG. 5 is a schematic diagram illustrating a stress distribution table representing compensation stresses corresponding to stress compensation points according to an embodiment of the present disclosure;

FIG. 6 is a vector diagram of an overlay error compensation amount according to an embodiment of the present disclosure;

FIG. 7 is a vector diagram illustrating an overlay residual distribution according to an embodiment of the present disclosure;

FIG. 8 is a schematic diagram illustrating a compensation effect of 24 rounds of overlay error compensations in an X-direction according to an embodiment of the present disclosure;

FIG. 9 is a schematic diagram illustrating a compensation effect of 24 rounds of overlay error compensations in a Y-direction according to an embodiment of the present disclosure; and

FIG. 10 is a schematic diagram of an apparatus for compensating an overlay error in a lithography process according to an embodiment of the present disclosure.

### DETAILED DESCRIPTION

A method and an apparatus for compensating an overlay error in a lithography process and a lithography machine according to the present disclosure may be applied to the field of semiconductor manufacturing. The above examples are merely illustrative and do not limit the application fields of the method and the apparatus for compensating the overlay error in the lithography process and the lithography machine according to the present disclosure.

In the specification, the claims and the drawings of the present disclosure, terms such as “first”, “second”, “third”, and “fourth” are merely for distinguishing objects rather than describing a specific order.

In embodiments of the present disclosure, words “as an example” and “for example” are merely for describing an example, an illustration, or an explanation. Any embodiment or design described as “as an example” or “for example” in the embodiments of the present disclosure shall not be interpreted as preferable or advantageous over other embodiments or designs. Rather, the words such as “as an example” or “for example” are intended to present relevant concepts in a specific manner.

The terms in the embodiments of the present disclosure are only for the purpose of explaining embodiments of the present disclosure, rather than limiting the present disclosure.

In order to enable those skilled in the art to better understand the technical solution according to the present disclosure, the technical solutions according to the embodiments of the present disclosure are described clearly and completely hereinafter with reference to the drawings in the embodiments of the present disclosure. Apparently, the described embodiments are only part of the embodiments according to the present disclosure, rather than all of the embodiments. Based on the embodiments of the present disclosure, all other embodiments obtained by those skilled in the art without any creative effort fall within the protection scope of the present disclosure.

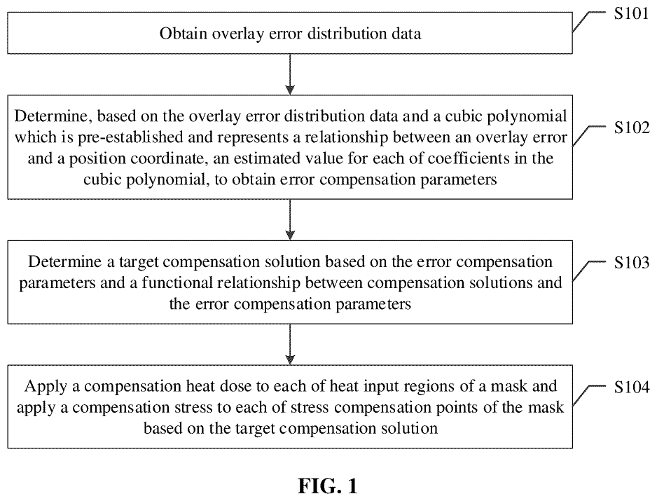

Reference is made to FIG. 1, which is a flowchart of a method for compensating an overlay error in a lithography process according to an embodiment of the present disclosure. The method may be performed by a compensation model.

As an example, the compensation model may be a finite element model. An input parameter for the compensation model may include, but is not limited to, physical parameters such as the thermal conductivity and expansion coefficient of a material of a mask, as well as environmental parameters like temperature variations in an operating environment of the lithography machine. A response of the mask during the lithography process, including a thermodynamic deformation response and a mechanical response to stress application, is accurately predicted by performing coupling calculation on multiple physical fields, such as a temperature field, a stress field, and a deformation field, and performing numerical simulation based on a compensation solution. Through the compensation model, error compensation parameters may be calculated based on overlay error distribution data and rigorous simulation on the overlay error compensation, thereby obtaining a target compensation solution.

In some embodiments, multiple compensation models may be pre-established to address various requirements, such as the lithography machine and/or the mask used, and the compensation accuracy desired. When the compensation model is selected, factors such as compensation accuracy, computational capability, adaptability, and scalability of the model may be comprehensively considered to select an appropriate compensation model. Subsequently, constraints are set for an output result (that is, the target compensation solution) of the compensation model based on factors such as a tolerance range of the process, a device performance corresponding to each compensation item, and production efficiency, to ensure that the target compensation solution does not exceed a physical limit of the device or cause other process anomalies.

The method for compensating the overlay error in the lithography process according to the embodiment of the present disclosure includes steps S101 to S104.

In step S101, overlay error distribution data is obtained.

As an example, lithography is performed on a wafer by using a current lithography parameter to obtain a lithographic pattern. Subsequently, a deviation between the lithographic pattern and a reference pattern is measured to obtain overlay error distribution data corresponding to the current lithography parameter. For instance, scanning is performed on the displayed lithographic pattern by using a high-resolution optical microscope with image recognition and measurement functions and through an automated measurement system, to precisely capture an offset of the lithographic pattern in an X axis and a Y axis, so as to obtain an overlay error δx and δy between the lithographic pattern and the reference pattern at each of acquisition points on the wafer. The measurement is performed in a clean and temperature-stable environment to prevent external interference from affecting data accuracy.

In an embodiment, the overlay error distribution data includes offset values between the lithographic pattern and the reference pattern at the acquisition points, and parameters such as an error distribution mode and a root-mean-square error. The overlay error distribution data may be stored in a table or matrix format, digitally processed, and packaged into a standard format suitable for inputting to a compensation model, facilitating overlay error compensation in subsequent steps. For example, each collected overlay error may be defined as a sum of an absolute mean value and three times the standard deviation of offset values at the acquisition points, that is, |mean|+3σ.

In step S102, based on the overlay error distribution data and a cubic polynomial which is pre-established and represents a relationship between an overlay error and a position coordinate, an estimated value of each of coefficients in the cubic polynomial is determined to obtain error compensation parameters.

In an embodiment, the cubic polynomial that represents the relationship between an overlay error and a position coordinate may be expressed as follows:

δₓ=k₁+k₃·x+k₅·y+k₇·x²+k₉·xy+k₁₁·y₂+k₁₃·x³+k₁₅·x²y+k₁₇·xy²+K₁₉·y³;

δy=k₂+k₄·y+k₆·x+k₇·y²+k₁₀·xy+k₁₂·x²+k₁₄·y³+k₁₆·y²x+k₁₈·yx²+k₂₀·x³.

where, k₁, k₂, . . . , k₂₀ represent error compensation parameters for compensating the overlay error of the lithography machine, δx represents an actually measured overlay error in the X direction, and δy represents an actually measured overlay error in the Y direction.

For example, coefficients (that is, the error compensation parameters) in the above cubic polynomial are fitted through the least squares to minimize the sum of squared errors between an actual overlay error (δx and δy) and a predicted overlay error (δx(xᵢ, yᵢ) and δy(xᵢ,yᵢ)), which is expressed as follows:

$$min {\sum }_{i = 1}^{n} {( δ {x}_{i} - δ x ( {x}_{i} , {y}_{i} ) )}^{2} ; min {\sum }_{i = 1}^{n} {( δ {y}_{i} - δ y ( {x}_{i} , {y}_{i} ) )}^{2}$$

Therefore, the estimated value of each of the coefficients k₁, k₂, . . . , k₂₀ in the cubic polynomial is determined, to obtain the error compensation parameters.

In an embodiment, after obtaining the estimated values of the coefficients, a P-value may be used to evaluate significance of an impact of each coefficient on the overlay error. Specifically, for the coefficient kⱼ, the following hypothesis testing may be performed.

In an original hypothesis H₀, kⱼ=0, which indicates that the coefficient kⱼ has no significant impact on the overlay error. In an alternative hypothesis Hₐ, kⱼ≠0, which indicates the coefficient kⱼ has a significant impact on the overlay error.

The P-value is a statistical concept used in hypothesis testing for measuring a probability of given data occurring when an original hypothesis is true. A small P-value indicates that the observed data is unlikely to occur when the original hypothesis is true. In this case, the original hypothesis may be rejected and the alternative hypothesis may be accepted. A large P-value indicates that the data is consistent with the original hypothesis, providing insufficient evidence to reject the original hypothesis.

The P-value may be calculated through a t-test, where a t-statistic tⱼ is expressed as:

$${t}_{j} = \frac{{\hat{k}}_{j}}{SE ( {\hat{k}}_{j} )}$$

where \hat{k}ⱼ is an estimated value of the coefficient kⱼ, and SE(\hat{k}ⱼ) is a standard deviation of the coefficient kⱼ.

Based on a t-distribution and a t-value, the P-value corresponding to the coefficient kⱼ may be calculated as follows: P-value=2×prob(T>|tⱼ|). The P-value is twice the probability of T being greater than |tⱼ|.

To more intuitively represent a significance level of the impact of the coefficient kⱼ on overlay error, a Log Worth value is introduced by converting the P-value into a logarithmic scale: Log Worth=−log₁₀(P-value).

For the Log Worth calculated in each of compensation solutions, a parameter kⱼ with Log Worth>1.3 is selected to simplify the model. Parameters kⱼ which have a significant impact on the overlay error are taken as error compensation parameters. Terms in the polynomial which respectively correspond to the error compensation parameters are categorized as critical polynomial terms affecting the actual overlay error.

In step S103, a target compensation solution is determined based on the error compensation parameters and a functional relationship between compensation solutions and the error compensation parameters.

The compensation solution includes compensation heat doses respectively corresponding to at least 20 heat input regions and compensation stresses respectively corresponding to multiple stress compensation points.

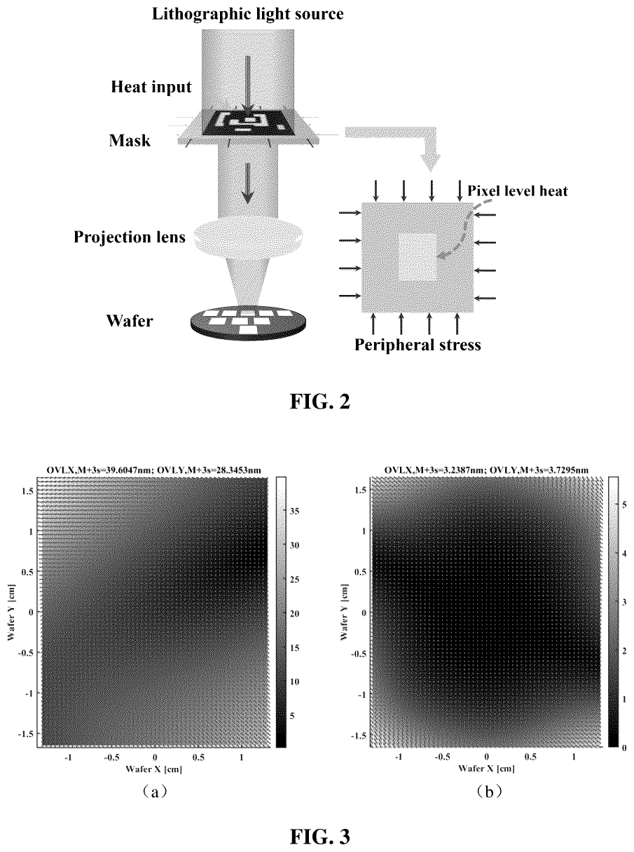

As shown in FIG. 2, FIG. 2 is a schematic diagram of an overlay error compensation mechanism according to an embodiment of the present disclosure. A lithographic light source illuminates a mask. Light passes through a projection lens and further illuminates a surface of a wafer, thereby forming a lithographic pattern on photoresist on the surface of the wafer. In the embodiment of the present disclosure, for overlay error compensation, the mask is divided into at least 20 heat input regions, so as to provide pixel-level heat for the regions, and at least 20 heat compensation solutions are designed. Multiple stress actuators are arranged at the periphery of the mask, so as to apply a peripheral stress to the mask through the stress actuators, and various stress compensation solutions are designed.

For example, the mask are divided into 143 heat input regions. These 143 heat input regions may be arranged in an equally spaced matrix including 11 heat input regions in a horizontal direction and 13 heat input regions in a vertical direction. Each heat input region is a rectangle with a length of 3 mm and a width of 2 mm. 16 stress actuators may be arranged at the periphery of the mask, with 4 actuators configured on each side. Therefore, 16 stress compensation solutions are designed for the peripheral hinges to provide peripheral stresses, based on fundamental principles of elastic deformation and torque balance of the mask.

It can be understood that the number and the dimension of the heat input regions may be flexibly configured based on requirements and a capability of a local heating system. For instance, the dimension of the heat input region may be reduced, and the heat input region is set as a rectangle with a length of 1.5 mm and a width of 1 mm. Accordingly, the number of the heat input regions are increased to ensure that the entire array composed of all the heat input regions covers the full mask.

As an example, statistical analysis on a functional relationship between all the compensation solutions and the error compensation parameters is performed to establish a functional relationship between compensation solutions and error compensation parameters. For instance, for 143 heat compensation solutions and 16 stress compensation solutions, statistical analysis is performed to obtain the distributions of error compensation parameters in these different compensation solutions. Algorithm optimization is performed to obtain a functional relationship between the 159 compensation solutions and the error compensation parameters.

A case that error compensation parameters are k₁, k₂, . . . , k₂₀ is taken as an example, the functional relationship between the 159 compensation solutions and the error compensation parameters is expressed as follows:

$$[ \begin{matrix}{h}_{1} \\ {h}_{2} \\ ⋮ \\ {h}_{143} \\ {f}_{1} \\ {f}_{2} \\ ⋮ \\ {f}_{16}\end{matrix} ] ∼ [ \begin{matrix}{k}_{1} \\ {k}_{2} \\ ⋮ \\ {k}_{20}\end{matrix} ] ;$$

where h₁, h₂, . . . , and h₁₄₃ represent compensation heat doses corresponding to the 143 thermal input regions, f₁, f₂, . . . , and f₁₆ represent compensation stresses at stress compensation points in the 16 stress compensation solutions.

According to the functional relationship between the compensation solutions and the error compensation parameters, the compensation amounts required to reduce the overlay error are simulated and calculated through the compensation model based on the measured overlay error distribution data, so as to obtain compensation requirements for the heat input regions and the stress compensation points, thereby determining the target compensation solution.

In step S104, based on the target compensation solution, a compensation heat dose is applied to each of the heat input regions of a mask and a compensation stress is applied to each of the stress compensation points of the mask.

As an example, the local heating system is driven based on the compensation heat doses corresponding to the heat input regions in the target compensation solution to apply the compensation heat doses to the heat input regions of the mask.

The local heating system may include a digital micro-mirror device (DMD), a heating light source, and an optical system. The DMD is a micro-electro-mechanical system (MEMS) device composed of millions of microscopic tiltable mirrors, each mirror is independently controllable to control the distribution of a heating light beam, so as to implement local heating. The heating light source may be ultraviolet (UV) or deep ultraviolet (DUV). The optical system includes a lens, a mirror, and a stop and is configured to focus light from the light source onto the DMD and project the reflected light from the DMD onto the surface of the wafer.

A heating pattern is determined based on the compensation heat doses corresponding to the heat input regions in the target compensation solution. Subsequently, based on the heating pattern, the optical system may be driven to modulate the heating light source and focus the heating light from the heating light source onto the micro-mirrors of the DMD. By adjusting a reflection direction and intensity of the heating light through the DMD, the heating light is modulated based on the heating pattern to form a specific light intensity distribution to be reflected onto the mask, so as to apply the compensation heat doses to the heat input regions of the mask. Therefore, a thermal expansion morphology of the mask is altered through local heating to correct the overlay error.

In an embodiment, after applying the compensation heat doses to the heat input regions of the mask, a current temperature of each of the heat input regions is obtained through a temperature sensor. Based on the current temperatures of the heat input regions and target temperatures of the heat input regions, a state of each of the micro-mirrors in the DMD is dynamically adjusted, to cause the current temperature of the micro-mirror to approach the target temperature, where the target temperature of the heat input region is a temperature that the heat input region approaches after the compensation heat dose is applied. For example, the state of the micro-mirror in the DMD is dynamically adjusted based on a feedback signal from the temperature sensor through a proportional-integral-derivative (PID) control algorithm, thereby precisely controlling a local heating process. The target temperature may be calculated based on an initial temperature of the mask prior to the overlay error compensation and the heat compensation dose corresponding to the heat input region in the target compensation solution.

As an example, a stress actuator is driven based on the compensation stress corresponding to the stress compensation point in the target compensation solution to apply a compensation stress onto the stress compensation point of the mask.

An overlay error caused by factors such as a heat effect, a stress variation, a mask error, a process fluctuation, and an environmental change during lithography is effectively addressed through heat compensation and stress compensation. The compensation solution may be dynamically adjusted based on recent overlay error distribution data, ensuring high stability and reliability during lithography even under an extreme process condition, and enabling the lithography process to achieve a predetermined precision.

Therefore, in the embodiments of the present disclosure, the compensation stress and the compensation heat doses corresponding to at least 20 heat input regions that are required to compensate for an overlay error are determined based on overlay error distribution data. Stress compensation and pixel-level heat compensation for the mask are implemented to induce a controlled mask deformation, so as to precisely compensate the overlay error in the lithography. Thereby, the overlay error in the lithography is effectively reduced, lithography precision is enhanced, high-precision pattern transfer for a pattern with a small feature size is implemented, product reliability and yield are improved, and cost of large-scale production is reduced.

Furthermore, the method for compensating the overlay error in the lithography process according to the embodiments of the present disclosure is applicable to various lithography technologies such as extreme ultraviolet lithography (EUVL), deep ultraviolet lithography (DUVL), nanoimprint lithography (NIL), and surface plasmon lithography (SPL), which has strong universality. The method provides a high-precision overlay error compensation solution based on heat compensation and stress compensation for fields like high-precision semiconductor manufacturing and micro/nano-structure processing, meeting diverse process and equipment requirements.

An example of compensating an overlay error in a lithography process according to the present disclosure is described as follows:

Reference is made to FIG. 3, which is a vector diagram illustrating an overlay error distribution according to an embodiment of the present disclosure. The distribution of \sqrt{dₓ²+d_{y}²} of overlay errors at various points within the field is shown in the vector diagram, and a superimposed error |mean|+36 in the X direction and a superimposed error |mean|+3σ in the Y direction are annotated in the vector diagram. The superimposed overlay error in the X direction may be represented by OVLx, and the superimposed overlay error in the Y direction may be represented by OVLy. The overlay error distribution is illustrated in an intuitive manner, enabling technicians to rapidly determine the overlay error that occurs during lithography under a current condition. FIG. 3(a) is a vector diagram illustrating an original overlay error distribution, and a case shown in FIG. 3(a) is denoted as Example 1. FIG. 3(b) is a vector diagram illustrating an overlay error distribution where the overlay error includes only higher-order terms, and a case shown in FIG. 3(b) is denoted as Example 2. The higher-order term refers to a cubic term in the cubic polynomial which represents a relationship between an overlay error and a position coordinate.

The vector diagram of overlay error distribution shown in FIG. 3 is inputted into the compensation model. The compensation model performs steps S101 to S104, that is, the compensation model automatically calculates a target compensation solution that minimizes the overlay error based on the overlay error distribution data, and performs the target compensation solution. A compensation calculation for the overlay error can achieve a nanometer-level precision.

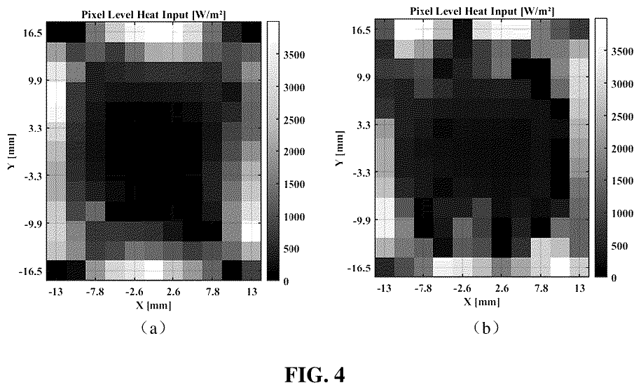

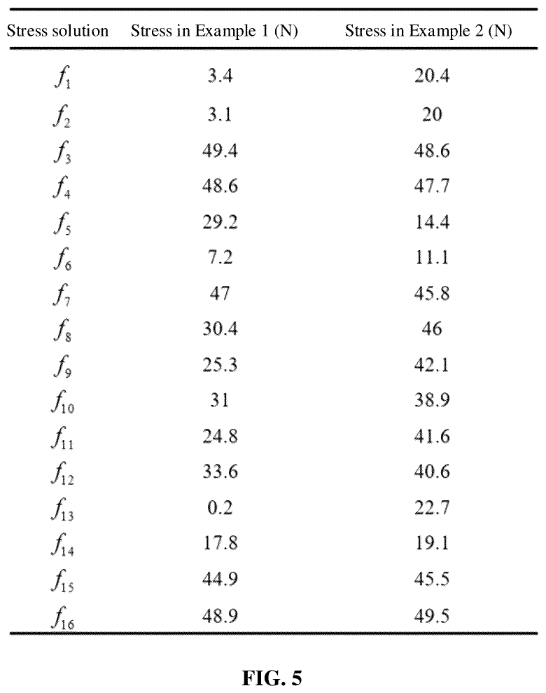

After obtaining the target compensation solution, the compensation model generates, based on the target compensation solution, a heating image (as shown in FIG. 4) showing the compensation heat doses corresponding to the heat input regions, and a stress distribution table (as shown in FIG. 5) showing the compensation stresses corresponding to the stress compensation points, thereby illustrating the compensation requirements for different regions. FIG. 4(a) is a heating image for Example 1, and FIG. 4(b) is a heating image for Example 2.

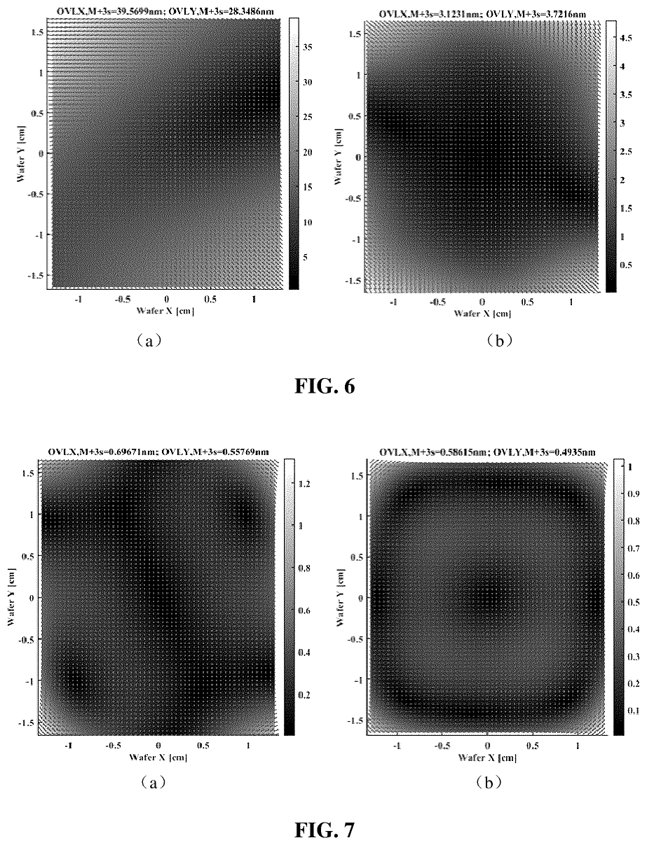

Subsequently, the compensation model generates a vector diagram of an overlay error compensation amount as shown in FIG. 6 based on the heating image shown in FIG. 4 and the stress distribution table shown in FIG. 5, facilitating evaluation of an overlay error compensation effect of the compensation solution. FIG. 6(a) is a vector diagram of an overlay error compensation amount for Example 1, and FIG. 6(b) is vector diagram of an overlay error compensation amount for Example 2. If the compensation effect is unsatisfactory, the process of determining a target compensation solution through the compensation model is continued until a compensation accuracy meet an expectation.

After completing the compensation for the overlay error in the lithography process, it is determined whether an actual compensation effectiveness meets an expected target performing measurement on a lithography result of a wafer from a current batch in the lithography. Furthermore, by analyzing and measuring the lithography precision of the current batch, the effectiveness of the target compensation solution is further evaluated. Based on a compensation effect for the process, the compensation model is adjusted through steps S101 to S104 to continuously optimize the compensation model.

In an embodiment, in combination with historical overlay error distribution data from multiple lithography processes, a variation trend of a residual overlay error after multiple overlay error compensations is analyzed, and a potential overlay error range and a compensation requirement for a next batch are predicted. Parameters such as a compensation heat dose and a compensation stress in the compensation model are adjusted, and a target compensation solution for the next overlay error compensation is optimized, to enhance an overlay error compensation effect.

To validate the overlay error compensation effect after the target compensation solution is performed, the overlay errors after compensation in Example 1 and Example 2 are measured point-by-point, and a vector diagram illustrating an overlay residual distribution is obtained as FIG. 7. FIG. 7(a) is a vector diagram of an overlay residual distribution for Example 1, and FIG. 7(b) is a vector diagram of an overlay residual distribution for Example 2. It can be observed that in Example 1, an overlay error in the X direction decreased from 39.6047 nm to 0.69671 nm, with 98.24% of the overlay error compensated, and the overlay error in the Y direction decreased from 28.3453 nm to 0.55769 nm, with 98.03% of the overlay error compensated. In Example 2, an overlay error in the X direction decreased from 3.2387 nm to 0.58615 nm, with 81.90% of the overlay error compensated, and the overlay error in the Y direction decreased from 3.7295 nm to 0.4935 nm, with 86.77% of the overlay error compensated.

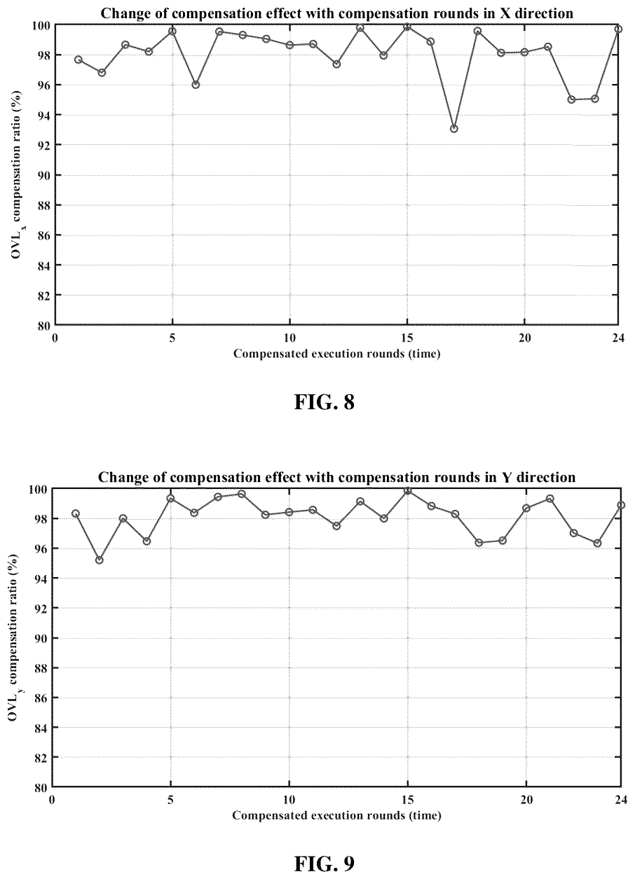

With the method for compensating the overlay error in the lithography process according to an embodiment of the present disclosure, 24 rounds of overlay error compensations are performed on an original overlay error. A compensation effect in the X-direction is shown in FIG. 8, achieving an average compensation efficiency of 98.05%. The compensation effect in the Y-direction is shown in FIG. 9, achieving an average compensation efficiency of 98.11%. The superimposed error |mean|+36 is reduced to below 1 nm, significantly enhancing the reliability of circuit connections in a semiconductor device and meeting a precision requirement of an advanced process node.

As an example, in the embodiments of the present disclosure, the lithography process specifically includes steps S1 to S3.

In step S1, a photoresist-coated wafer is placed onto a wafer stage inside a lithography machine by using a robotic arm in the lithography machine. The wafer may be fixed by using a chuck, such as a vacuum chuck to prevent displacement of the wafer during exposure. A mask is placed onto a mask stage inside the lithography machine by using the robotic arm in the lithography machine. The mask may be fixed by a mechanical fixture or by vacuum adsorption or the like to prevent displacement or deformation of the mask during exposure. A pattern side of the mask faces a surface of the wafer and is aligned with an optical axis of the light source.

After the wafer and the mask are placed inside the lithography machine, alignment operation is performed on the wafer and the mask through an alignment system of the lithography machine. As an example, the alignment system of the lithography machine adjusts a wafer position first to achieve preliminary alignment between the wafer and the wafer stage, then adjusts a mask position to achieve preliminary alignment between the mask and the mask stage and ultimately performs alignment between the wafer and the mask.

The alignment between the wafer and the mask may be achieved through coarse alignment followed by fine alignment. In the coarse alignment, only two alignment marks, such as two alignment marks far apart on the wafer, are typically required. In the fine alignment, multiple alignment marks, such as at least 20 alignment marks, are required. By locating these multiple alignment marks, a precise position of the wafer and the mask during exposure is calculated through the alignment system, to reduce the overlay error.

In step S2, the photoresist-coated wafer is exposed by a light source within the lithography machine. The photoresist undergoes a chemical reaction under illumination, forming a lithographic pattern based on a pattern of the mask.

In step S3, the wafer is immersed into a developing solution to remove the exposed photoresist (a positive photoresist) or the unexposed photoresist (a negative photoresist), to obtain a photoresist mask.

The lithography machine is a critical tool for performing the lithography process. An appropriate type of lithography machine is selected based on the type of the lithography technology employed. For example, a lithography machine corresponding to a lithography process such as extreme ultraviolet lithography (EUVL), deep ultraviolet lithography (DUVL), nanoimprint lithography (NIL), or surface plasmon lithography (SPL) is selected. The lithography machine operates in a cleanroom environment and is equipped with a high-precision alignment system to ensure precise alignment between the mask and the wafer. During operation of the lithography machine, environmental conditions such as temperature, humidity, and pressure of the environment where the lithography machine is located must be strictly controlled to prevent environmental variations from affecting lithography precision.

The mask is a precise high-resolution template, which is typically made from a stable, high-temperature-resistant material such as quartz or glass. The mask is provided with a pattern at a micrometer or a sub-micrometer level. During the lithography process, when the mask is illuminated by a light source in the lithography machine, the pattern on the mask is transferred to a photoresist located on the side of the mask away from the light source, forming a lithographic pattern.

The wafer is a finely processed semiconductor substrate. The surface of the wafer may be polished or cleaned to remove impurities or oxide layers on the surface, thereby ensuring that the cleanliness of the surface of the wafer is within an allowable range of the process. The semiconductor substrate is made from silicon, germanium, quartz glass or other semiconductor materials. The photoresist on the surface of the wafer is coated in a spin coating manner or the like, ensuring the resulting photoresist layer has uniform thickness that falls within an allowable range of the process. In an embodiment, prior to photoresist coating to the surface of the wafer, a layer of auxiliary transition material or an anti-reflective coating is formed on the surface of the wafer to minimize an impact of reflected light on the exposure effect.

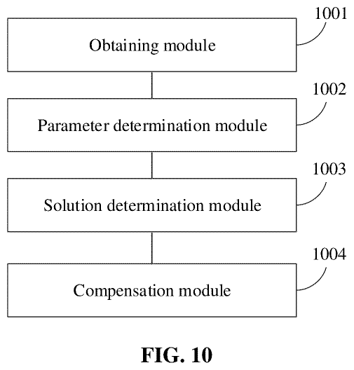

Reference is made to FIG. 10, which is a schematic diagram of an apparatus for compensating an overlay error in a lithography process according to an embodiment of the present disclosure. The apparatus includes: an obtaining module 1001, a parameter determination module 1002, a solution determination module 1003, and a compensation module 1004.

The obtaining module 1001 is configured to obtain overlay error distribution data under a current lithographic condition.

The parameter determination module 1002 is configured to determine, based on the overlay error distribution data and a cubic polynomial which is pre-established and represents a relationship between an overlay error and a position coordinate, an estimated value of each of coefficients in the cubic polynomial, to obtain error compensation parameters.

The solution determination module 1003 is configured to determine a target compensation solution based on the error compensation parameters and a functional relationship between compensation solutions and the error compensation parameters. The compensation solution includes compensation heat doses corresponding to at least 20 heat input regions and compensation stresses corresponding to multiple stress compensation points.

The compensation module 1004 is configured to apply a compensation heat dose to each heat input region of the heat input regions of a mask and apply a compensation stress to each stress compensation point of the stress compensation points of the mask based the target compensation solution.

Therefore, in the embodiments of the present disclosure, the compensation stress and the compensation heat doses corresponding to at least 20 heat input regions that are required to compensate for an overlay error are determined based on overlay error distribution data. Stress compensation and pixel-level heat compensation for the mask are implemented to induce a controlled mask deformation, so as to precisely compensate the overlay error in the lithography. Thereby, the overlay error in the lithography is effectively reduced, lithography precision is enhanced, high-precision pattern transfer for a pattern with a small feature size is implemented, product reliability and yield are improved, and cost of large-scale production is reduced.

In an embodiment, the compensation module 1004 is configured to determine a heating pattern based on the compensation heat doses corresponding to the heat input regions in the target compensation solution; drive, based on the heating pattern, an optical system to modulate a heating light source, and drive a digital micro-mirror device to reflect heating light from the modulated heating light source onto the mask, to apply the compensation heat doses to the heat input regions of the mask.

In an embodiment, the parameter determination module 1002 is configured to determine, based on the overlay error distribution data and a cubic polynomial which is pre-established and represents a relationship between an overlay error and a position coordinate, an estimated value of each of coefficients in the cubic polynomial through least squares, to obtain error compensation parameters.

In some embodiments, the apparatus for compensating the overlay error in the lithography process according to an embodiment of the present disclosure further includes a temperature adjustment module. The temperature adjustment module is configured to obtain a current temperature of each heat input region of the heat input regions through a temperature sensor, and dynamically adjust, based on the current temperature of the heat input region and a target temperature of the heat input region, a state of each of micro-mirrors in the digital micro-mirror device, to cause the current temperature to approach the target temperature. The target temperature of the heat input region is a temperature that the heat input region approaches after the compensation heat dose is applied.

In addition, a lithography machine is provided according to the present disclosure. The lithography machine includes a controller, a stress actuator, and a local heating system.

The controller is electrically connected to the stress actuator and the local heating system.

The controller is configured to drive the stress actuator to apply a compensation stress to each stress compensation point of stress compensation points of a mask and drive the local heating system to apply a compensation heat dose to each heat input region of heat input regions of the mask, based on the method for compensating the overlay error in the lithography process according to any of the embodiments described above.

The local heating system includes a digital micro-mirror device, a heating light source, and an optical system. The local heating system is configured to modulate, in response to driving by the controller, the heating light source through the optical system to focus heating light from the heating light source onto each of micro-mirrors in the digital micro-mirror device, and reflect the heating light onto the mask through the digital micro-mirror device, to apply the compensation heat dose to the heat input region of the mask.

It should be noted that embodiments in this specification are described in a progressive way, the same and similar parts among the embodiments may refer to each other, and each of the embodiments emphasizes differences from other embodiments. Especially, for the apparatus and system embodiments, since they are similar with the method embodiments, the description of the apparatus and system is simple, and reference may be made to the relevant part of the method embodiments. The apparatus and system embodiments described above are only exemplary, in which the units described as separate components may be or not be separated physically, components shown as units may be or not be physical units, that is, the components may be located at one place or distributed across multiple network units. Some or all of the modules may be adopted as needed to achieve the object of the solutions of the embodiments. Those skilled in the art may understand and implement the solution without any creative effort.

The above description is only a specific embodiment of the present disclosure, and the protection scope of the present disclosure is not limited thereto. Any changes or replacements that may be easily conceived by those skilled in the art within the technical scope disclosed in the present disclosure should fall within the protection scope of the present disclosure. Therefore, the protection scope of the present disclosure should be subject to the protection scope of the claims.

1. A method for compensating an overlay error in a lithography process, comprising:
obtaining overlay error distribution data;
determining, based on the overlay error distribution data and a cubic polynomial which is pre-established and represents a relationship between an overlay error and a position coordinate, an estimated value of each of coefficients in the cubic polynomial, to obtain error compensation parameters;
determining a target compensation solution based on the error compensation parameters and a functional relationship between compensation solutions and the error compensation parameters, wherein each of the compensation solutions comprises compensation heat doses corresponding to at least 20 heat input regions and compensation stresses corresponding to a plurality of stress compensation points; and
applying a compensation heat dose to each heat input region of the at least 20 heat input regions of a mask and applying a compensation stress to each stress compensation point of the plurality of stress compensation points of the mask based on the target compensation solution.

2. The method according to claim 1, wherein the applying a compensation heat dose to each heat input region of the at least 20 heat input regions of a mask based on the target compensation solution comprises:
determining a heating pattern based on the compensation heat dose corresponding to the heat input region in the target compensation solution; and
driving, based on the heating pattern, an optical system to modulate a heating light source, and driving a digital micro-mirror device to reflect heating light from the modulated heating light source onto the mask, to apply the compensation heat dose to the heat input region of the mask.

3. The method according to claim 2, wherein after driving, based on the heating pattern, an optical system to modulate a heating light source, and driving a digital micro-mirror device to reflect heating light from the modulated heating light source onto the mask, to apply the compensation heat dose to the heat input region of the mask, the method further comprises:
for each heat input region of the at least 20 heat input regions,
obtaining a current temperature of the heat input region through a temperature sensor; and
dynamically adjusting, based on the current temperature of the heat input region and a target temperature of the heat input region, a state of each of micro-mirrors in the digital micro-mirror device, to cause the current temperature to approach the target temperature, wherein the target temperature of the heat input region is a temperature that the heat input region approaches after the compensation heat dose is applied.

4. The method according to claim 1, wherein the number of the heat input regions is 143.

5. The method according to claim 4, wherein the 143 heat input regions are arranged as an equally spaced matrix comprising 11 heat input regions in a horizontal direction and 13 heat input regions in a vertical direction.

6. The method according to claim 1, wherein each of the heat input regions is a rectangular with a length of 3 mm and a width of 2 mm.

7. The method according to claim 1, wherein the determining, based on the overlay error distribution data and a cubic polynomial which is pre-established and represents a relationship between an overlay error and a position coordinate, an estimated value of each of coefficients in the cubic polynomial, to obtain error compensation parameters comprises:
determining, based on the overlay error distribution data and the cubic polynomial which is pre-established and represents the relationship between the overlay error and the position coordinate, the estimated value of the coefficient in the cubic polynomial through least squares, to obtain the error compensation parameters.

8. An apparatus for compensating an overlay error in a lithography process, comprising:
an obtaining module,
a parameter determination module,
a solution determination module, and
a compensation module, wherein
the obtaining module is configured to obtain overlay error distribution data under a current lithographic condition;
the parameter determination module is configured to determine, based on the overlay error distribution data and a cubic polynomial which is pre-established and represents a relationship between an overlay error and a position coordinate, an estimated value of each of coefficients in the cubic polynomial, to obtain error compensation parameters;
the solution determination module is configured to determine a target compensation solution based on the error compensation parameters and a functional relationship between compensation solutions and the error compensation parameters, wherein each of the compensation solutions comprises compensation heat doses corresponding to at least 20 heat input regions and compensation stresses corresponding to a plurality of stress compensation points; and
the compensation module is configured to apply a compensation heat dose to each heat input region of the at least 20 heat input regions of a mask and apply a compensation stress to each stress compensation point of the plurality of stress compensation points of the mask based on the target compensation solution.

9. A lithography machine, comprising:
a controller,
a stress actuator, and
a local heating system, wherein
the controller is electrically connected to the stress actuator and the local heating system, and is configured to:
based on the method for compensating the overlay error in the lithography process according to claim 1, drive the stress actuator to apply a compensation stress to each stress compensation point of stress compensation points of a mask and drive the local heating system to apply a compensation heat dose to each heat input region of heat input regions of the mask.

10. The lithography machine according to claim 9, wherein the local heating system comprises a digital micro-mirror device, a heating light source, and an optical system, wherein
the local heating system is configured to modulate, in response to driving by the controller, the heating light source through the optical system to focus heating light from the heating light source onto each of micro-mirrors in the digital micro-mirror device, and reflect the heating light onto the mask through the digital micro-mirror device, to apply the compensation heat dose to the heat input region of the mask.
